(19) United States
(12) Patent Application Publication
(10) Pub. No.: US 2007/0054048 A1
(43) Pub. Date: Mar. 8, 2007

(54) Extended deposition range by hot spots

(76) Inventors: Suvi Haukka, Helsinki (FI); Eva Tois, Espoo (FI)

Correspondence Address: KNOBBE MARTENS OLSON & BEAR LLP, 2040 MAIN STREET, FOURTEENTH FLOOR, IRVINE, CA, 92614, US

(21) Appl. No.: 11/221,574

(22) Filed: Sep. 7, 2005

(51) Int. Cl. C23C 16/00

(52) U.S. Cl. 427/248.1

(57) ABSTRACT

A catalytic reactant with a low activation energy barrier for oxide formation can be used to facilitate atomic layer deposition type reactions at reduced temperatures, thus increasing the quality of the deposited films. An initial reaction with a catalytic reactant provides localized heat at the substrate surface in the vicinity of the reactant. This localized heat facilitates a second reaction and deposition of the desired thin film. The processes may be used to deposit arrays of nanodots.

### I. FIELD OF THE INVENTION

The invention relates generally to the field of semiconductor manufacturing and more particularly to deposition upon a substrate.

### II. BACKGROUND OF THE INVENTION

Atomic Layer Deposition (ALD) processes are based on sequential self-saturating surface reactions. Examples of these processes are described in detail in U.S. Pat. Nos. 4,058,430 and 5,711,811.

Atomic Layer Deposition (ALD) processes are self-limiting, whereby alternated pulses of reaction precursors saturate a substrate and leave no more than one monolayer of material per pulse. The precursors and deposition conditions are selected to ensure self-saturating reactions.

Precursors are typically pulsed into the reaction chamber in an inert carrier gas. The precursors are selected to provide self-limiting reactions such that the amount of material that is deposited on a surface. For example, the adsorbed layer from one pulse leaves a surface termination that is non-reactive with the gas phase reactants of the same pulse. A subsequent pulse of different reactants reacts with the previous termination to enable continued deposition. Thus, each cycle of alternated pulses leaves no more than about one molecular layer of the desired material. Additionally, the conditions are such that no more than a monolayer forms so that the process is self-terminating or saturative. For example, deposition temperatures are maintained above the precursor condensation temperatures and below the precursor thermal decomposition temperatures. At temperatures above the thermal decomposition temperature, break down of the reagents will occur and the self-terminating nature of the deposition can be lost.

Additionally, the pulses of source chemical are separated from each other by a purging flow of inert gas. This separation of the source chemicals and the proper choice of source chemicals prevents gas-phase reactions between gaseous reactants and enables self-saturating surface reactions. This allows for film growth without strict temperature control of the substrate or precise dosage control of the reactants. Surplus reactants and byproducts are removed from the chamber, such as by a purging flow of inert gas, before the next reactive chemical pulse is introduced. Undesired gaseous molecules are effectively removed from the reaction chamber by keeping the gas flow speeds high. The purging gas pushes the extra molecules towards the vacuum pump that is used to maintain a suitable pressure in the reaction chamber.

Thus, ALD provides for rapid, uniform, controlled, and highly conformal film growth. The principles of ALD type processes have been presented by T. Suntola, e.g. in the Handbook of Crystal Growth 3, Thin Films and Epitaxy, Part B: Growth Mechanisms and Dynamics, Chapter 14, Atomic Layer Epitaxy, pp. 601-663, Elsevier Science B.V. 1994.

### III. SUMMARY OF THE EMBODIMENTS

Some of the embodiments are directed towards overcoming the temperature constraints described above by providing a way to increase the localized temperature on the substrate surface. In this way, high quality thin films are obtained at lower deposition temperatures.

In one aspect, methods are provided for thin film deposition by ALD type processes in which a first low activation energy reaction is performed that requires a first amount of activation energy and results in the creation of a first amount of heat. A high activation energy reaction is then performed that requires a second amount of activation energy greater than the first amount. The high activation energy reaction is facilitated and/or driven to proceed by the first amount of heat from the low activation energy reaction.

In some embodiments, a thin film is deposited on a substrate by an atomic layer deposition (ALD) type process comprising a plurality of cycles. At least one cycle comprises contacting a primary reactant to a surface of the substrate to form no more than about one monolayer and contacting a catalytic reactant to the substrate surface. The substrate is then contacted with an oxygen-containing reactant such that formation of an oxide of the catalytic reactant generates a localized amount of heat that facilitates formation of an oxide of the primary reactant. Excess reactant may be removed from the reaction chamber between provision of each reactant to the reaction chamber.

The primary reactant may be a metal reactant, such as a metal beta-diketonate or cyclopentadienyl compound. In some embodiments the primary reactant is a rare earth metal compound. In other embodiments the primary reactant is an alkali or alkaline earth metal compound. In still other embodiments the primary reactant is a silicon compound.

In some embodiments the catalytic reactant comprises a metal. For example, the catalytic reactant may be an alkyl compound, an acetylacetonate or a metal alkoxide. In some embodiments the catalytic reactant is an aluminum compound, such as TMA. In other embodiments the catalytic reactant is a titanium compound. The catalytic reactant may also be a compound that does not comprise a metal. For example, the catalytic reactant may be selected from the group consisting of acetylacetones and alcohols.

The oxygen containing reactant is not limited in any way and may be, for example, ozone or water.

In another aspect of the invention, the ALD type processes can be used to produce an array of nanodots on a substrate. In some embodiments nanodots are created on a substrate by a process in which a primary reactant is forms no more than about one monolayer on the surface of a substrate. A catalytic reactant is then provided that contacts the substrate surface and chemisorbs to one or more available binding sites. The primary and catalytic reactants on the substrate surface are contacted with an oxygen containing reactant, such that formation of an oxide of the catalytic reactant generates a zone of increased heat that facilitates formation of an oxide of the primary reactant within the zone of increased heat. The location of the catalytic reactant is such that all of the zones of increased heat do not overlap, leading to the generation of nanodots of the oxide of the primary reactant.

### IV. BRIEF DESCRIPTION OF THE FIGURES

FIGS. 1A-D depict a series of steps for one embodiment involving primary, exothermic, and oxygen containing reactants in a low temperature deposition process.

### V. DETAILED DESCRIPTION

The ability to modulate the temperature of the surface of a wafer during the deposition of a precursor can have many uses, especially in ALD. For example, a given reaction chamber temperature may be desirable for driving a particular reaction but may adversely affect one or more of the precursors. Some precursors may tolerate a higher temperature while others may start to decompose at the same temperatures. Thus, one temperature may be desirable for the initial chemisorption of a reactant onto a surface as it avoids decomposition of the reactant, but a higher temperature may be desired for modification of that initial layer. Such a modification can be, for example, removal of ligands from the absorbed reactant in order to obtain a pure film and/or reaction with a second reactant to form a compound, such as in the decomposition of carbonate from a La(thd)₃ film to remove the thd (2,2,6,6-tetramethyl-3,5-heptanedionato) ligands. While the temperature of the entire chamber or substrate could conceivably be changed between chemisorption and reaction, this is not practical. Thus, other methods of adjusting the temperature, especially those that are faster or more localized, would be advantageous. The inventors have found a way of adjusting local temperature to facilitate ALD reactions. This is done by using reactants that can result in exothermic reactions. In other words, an exothermic first reaction results in the production of heat, which facilitates a second reaction. In some embodiments, the ability to create localized areas of heat on a surface also allows one to create regular arrays of nanodots on a surface.

In some aspects, general methods are provided for using exothermic reactions to adjust the temperature of the local reaction area. In one embodiment, a substrate surface can be pulsed with a primary reactant (e.g., a metal reactant) so that at most a molecular monolayer of the primary reactant chemisorbs on the surface (in a self-limiting manner). Any excess primary reactant vapor can be removed from the reaction space by purging and/or evacuation. Because of steric hindrance or lack of ability to utilize certain binding sites, some of the potential binding sites may remain free.

Next, a catalytic reactant (e.g., a second metal reactant) is introduced into the reaction chamber. The catalytic reactant chemisorbs to the remaining binding sites on the surface that are not covered by the primary reactant. As used herein, a “catalytic reactant” is one that has a low activation energy barrier for oxide formation relative to the primary reactant, such that oxide formation results in the release of heat. Excess catalytic reactant vapor is removed from the reaction space by purging and/or evacuation.

An oxygen containing reactant is then introduced into the reaction space. The temperature of the substrate can initially be set to a level sufficient to drive a reaction between the catalytic reactant and the oxygen containing reactant, but low enough to avoid decomposition of the primary reactant so that decomposition does not disturb the formation of the monolayer of the primary reactant. In some embodiments, the upper boundary of the temperature is set so that the primary reactant is not degraded until after it has been chemisorbed onto a surface. In some embodiments, the substrate temperature is high enough that the additional heat generated by the local exothermic reaction will drive the reaction between the primary reactant and the oxygen containing reactant.

The oxygen containing reactant reacts with the catalytic reactant molecules, which have chemisorbed on the surface, because of lower activation energy for this reaction. The catalytic reactant can form a strong bond with oxygen. This local oxide formation reaction releases thermal energy and the local temperature increases (creating a hot spot) to a point at least sufficient for activating, facilitating, and/or driving the reaction between the primary reactant and the oxygen containing reactant. In this way, a monolayer of a compound metal oxide is formed on the substrate. Reaction byproducts and excess oxygen containing reactant are removed from the reaction space by purging and/or evacuation.

To summarize, one embodiment of the method can be described as involving two reactions, a first reaction involving a catalytic reactant that is exothermic in the first reaction (e.g., oxide formation) and a second reaction between a primary reactant and, typically, an oxygen-containing reactant. The second reaction generally requires more activation energy than is available from the temperature of the bulk substrate alone. Thus, heat produced from the first reaction helps to drive the second reaction. This additional heat can allow for the formation of an oxide of the primary reactant under reaction chamber temperatures that would otherwise be too low for adequate reaction of the primary reactant to produce a film of the desired quality and/or composition. This additional source of heat can provide a change in temperature at the surface of the wafer when desired (e.g., after the primary reactant has been chemisorbed rather than before). As will be appreciated by one of skill in the art, both reactions can occur simultaneously on a single wafer, such that the terms “first” and “second” do not necessarily imply a reaction sequence. In a preferred embodiment, the deposition is by Atomic Layer Deposition (ALD) or any self-limiting process where a monolayer or partial monolayer can be formed on a surface. The thin films made by the invention can be applied, e.g., to capacitor structures in integrated circuits.

Various steps and aspects of the compositions and methods involved are discussed in greater detail in the following paragraphs. Other variations and contexts will be apparent to the skilled artisan.

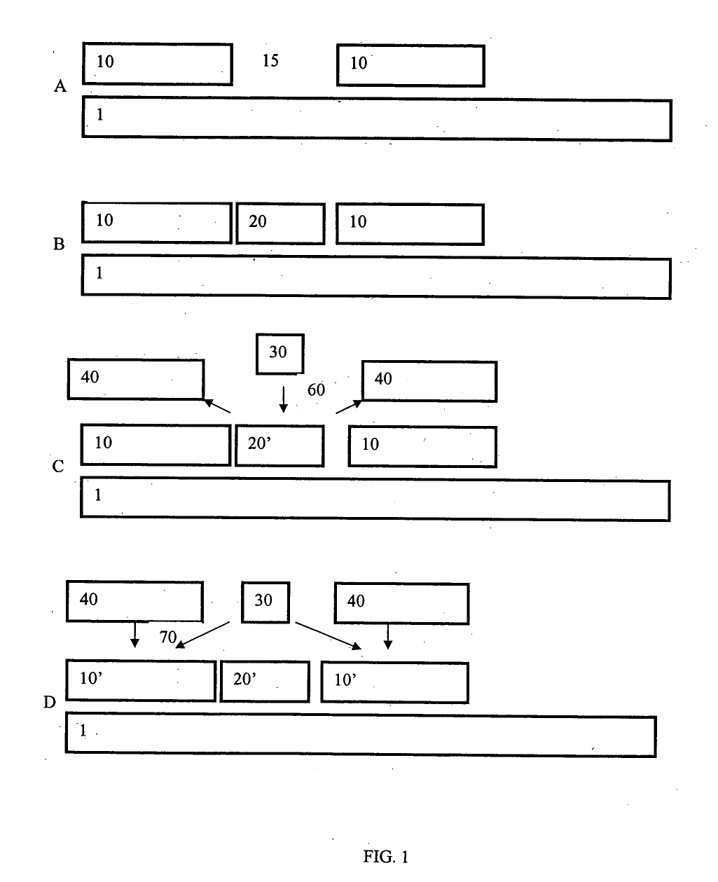

One embodiment is depicted in FIGS. 1A-1D. In FIG. 1A, a substrate 1, such as a wafer, is contacted with a primary reactant 10 (including a component of the film to be deposited) until a monolayer is formed and the surface is saturated. Any excess reactant can be purged out of the system. Following this, a catalytic reactant 20 is pulsed onto the surface, resulting in the arrangement of reactants on the surface as shown in FIG. 1B. Excess catalytic reactant 20 is then purged from the system. As will be appreciated by one of skill in the art, the monolayer established by the primary reactant 10 can determine the surface that will be available to which the catalytic reactant 20 can chemisorb. In some embodiments, the catalytic reactant 20 will only be able to chemisorb to those reactive sites 15 on the surface of the substrate 1 that are still exposed, e.g., that are not covered by the primary reactant 10 (as shown in FIG. 1A) due to steric hindrance or lack of ability to utilize certain binding sites. Thus, in some embodiments, the addition of the catalytic reactant 20 to the wafer surface 1, will result in the formation of a monolayer comprising the primary reactant 10 and the catalytic reactant 20, with those sections of the surface 1 that are large enough to allow the catalytic reactant 20 to bind having the catalytic reactant 20 (as depicted in FIG. 1B).

Following the establishment of the monolayer of the primary reactant 10 and the catalytic reactant 20, an oxygen containing reactant 30 is then added, as shown in FIG. 1C. Because of the lower activation energy, the catalytic reactant 20 is more likely to react with the oxygen containing reactant 30, in a first reaction 60, to generate a localized increase in heat 40 and an formation of an oxide of the catalytic reactant 20′. The required activation energy for the first reaction can be provided by the heat in the bulk substrate. The localized increase in heat 40, when combined with the heat in the bulk substrate, provides additional energy for the second reaction 70, e.g., the oxide formation of or removal of various ligands from the primary reactant 10 to leave a reaction product 10′, as shown in FIG. 1D. Thus, the heat 40 from the first reaction facilitates a more complete second reaction 70. The increase in local temperature due to the generation of localized heat 40 allows one to start or maintain the controlled temperature of the bulk substrate at a relatively low level. That is, at a level that does not significantly produce decomposition of the primary reactant. Additionally, this method of changing temperature allows one to avoid having to adjust the controlled temperature of the reaction chamber. Further, this method can allow one to restrict the amount of heat on a substrate to certain localized areas on the substrate surface, allowing greater manipulation of the areas of reactivity on the surface of the wafer.

One difference between the primary and the catalytic reactant is that the reaction between the catalytic reactant and oxygen containing reactant (i.e., the first reaction) requires less activation energy than the reaction involving the primary reactant (i.e., the second reaction). The first reaction provides activation energy for, or facilitates, the second reaction, e.g., the first reactant is exothermic when reacted and the second reaction is facilitated by this additional heat. In one embodiment, heat from the first reaction allows for effective completion of the second reaction. Effective completion can mean any improvement from a system without the catalytic reactant, for example, an improvement of at least 10%, more preferably at least 100% and most preferably at least 150 percent of an improvement in reacted primary reactant. An improvement can also be measured in percent of primary reactant modified appropriately. Any improvement over a system lacking the catalytic reactant can be sufficient, for example at least 40-50%, 50-60%, 70-80% or 80-90%, preferably greater than 90% and most preferably greater than 99% completion of the reaction involving the primary reactant.

In a preferred embodiment, the energetic barrier for oxide formation 60 of the catalytic reactant 20 is relatively low. That is, there is sufficient initial energy (heat) available in the heated substrate to drive the oxide formation reaction 60. Additionally, the energy state of the oxide of the catalytic reactant 20′ is also low compared to the energy state of the catalytic reactant 20, thus, the end result of the oxide formation reaction 60 is the production of heat. The energy 40 given off by the oxide formation reaction 60 provides the additional activation energy for the reaction 70 of the primary reactant 10 (e.g., oxide formation). The amount of activation energy required for completion of the second reaction 70 is more than is supplied by the bulk temperature of the substrate, but less than is supplied by the heated substrate and the heat from the first oxide formation reaction 60. This allows the primary reactant 10 to form an oxide even when the temperature of the reaction chamber remains relatively low. Thus, changes in the effective temperature of the reactants can be achieved without having to change the temperature of the substrate, which, in the case of a hot wall reactor, is also the temperature of the primary reactant chamber. Additionally, as both the primary and catalytic reactants are already chemisorbed onto the wafer surface, this additional heat need not adversely impact the arrangement of the monolayer of the primary reactant or cause other undesirable effects such as decomposition of the reactant on the walls of the reactor. In other words, the risk of the primary reactant undergoing degradation is reduced because the monolayer is already formed when the local temperature is increased to a level that increases the desired reaction.

Chemisorption of the primary reactant is typically followed by chemisorption of the catalytic reactant, although in some embodiments this can be reversed and the catalytic reactant can be provided first. In some embodiments, the primary and catalytic reactants can be added to the surface simultaneously. As will be appreciated by one of skill in the art, the physical characteristics of the primary reactant can influence the number of binding sites available and thus the amount of the catalytic reactant that is able to chemisorb. Thus, the resulting monolayers can vary depending upon how the two reactants associate with the surface of the wafer, interact with each other, and the size and conformation of the various reactants, including how they utilize different surface sites. Some monolayers can be primarily the primary reactant, and yet others can be primarily the catalytic reactant.

One of skill in the art will appreciate how these various components can be manipulated to achieve the desired results in light of the present teachings. One such factor that can be varied is the order of administration. When the catalytic reactant is added after the primary reactant, then the space available on the wafer for binding of the catalytic reactant will be the gaps resulting from incomplete occupation of reactive sites by the primary reactant. For example, in an ALD based process, the addition of the primary reactant to the surface will result in the establishment of a self-limiting monolayer of the primary reactant on the surface. Steric interactions between primary reactant molecules or lack of ability to utilize certain reactive sites will result in occupation of less than all reactive sites on the substrate. That is, some reactive sites will remain, even though no more of the primary reactant can bind to those sites. If the catalytic reactant is small enough or if it can utilize the reactive sites that the primary reactant cannot utilize, it can bind in the remaining space. One can adjust size of the catalytic and/or primary reactant to adjust the composition of the monolayer. Addition of the catalytic reactant after the primary reactant has been added will allow for the catalytic reactant to chemisorb only to the surface in areas that are exposed enough to allow the catalytic reactant to bind to the surface and vice versa.

As will be appreciated by one of skill in the art, the primary reactant need not necessarily be applied to the surface first; however, applying the primary reactant after the catalytic reactant has been added will result in the monolayer created by the catalytic reactant determining the location, distribution, and amount of the primary reactant and affects composition in cases where both contribute to compound. This reversed order can allow a much greater amount of catalytic reactant to bind to the substrate and alternately generate a much greater amount of localized heat. An alternative way of generating additional heat is to use a catalytic reactant that is highly exothermic. In alternative embodiments, the catalytic reactant can bind to the surface of the monolayer formed by the primary reactant.

In embodiments in which the distribution of the catalytic reactants are consistent and of a relatively high concentration throughout the monolayer, then the entire monolayer will be an area of localized heat, as all of the primary reactant will be close to a source of heat, e.g., a catalytic reactant. In this embodiment, “localized” can refer to surface localized temperature. In embodiments in which the catalytic reactants are relatively scarce or unevenly distributed, the entire surface will not be exposed to an increase in localized temperature; thus, not all of the primary reactant will be affected by the increased temperature. In other words, the distance between sections of the wafer surface with catalytic reactants is greater than the area heated by the formation of an oxide of the catalytic reactant (the zone of increased heat). Thus, when the distance between catalytic reactant molecules is greater than the distance covered by the zone of increased heat, then there will be areas of the primary reactant that are covered by the zone of increased heat and areas that are not covered by the zone of increased heat. In these embodiments, localized denotes that isolated sections of the surface are heated.

This relationship of heat distribution and catalytic reactant distribution can be used to selectively oxidize various areas of a surface to, for example, create nanodots. For example, a first layer of a primary reactant is chemisorbed onto a surface. The monolayer created by the primary reactant allows only a relatively small number of spaces to be available on the surface to which the catalytic reactant can chemisorb. As the number and position of each catalytic reactant is relatively few and far between, formation of an oxide of the catalytic reactant need not produce sufficient heat across the entire surface of the monolayer of the primary reactant to allow oxide formation across the entire surface of primary reactant to occur. Thus, only the area of primary reactant around the catalytic reactant will form oxide.

Upon the addition of a second layer of the primary reactant via ALD, only those areas of the first monolayer of the primary reactant that were exposed to temperatures sufficient (e.g., in the zone of increased heat) to allow oxide formation will allow chemisorption of a second layer of the primary reactant, as the unreacted surfaces of the first monolayer of the primary reactant would still maintain its self-limiting properties. This is then followed by chemisorbing a second layer of the catalytic reactant to the surface, which, again, will only chemisorb to areas with enough space and the right properties, e.g., those areas where the catalytic reactant was previously chemisorbed and formed an oxide. By repeating these steps, an array of nanodots can be generated.

As will be appreciated by one of skill in the art, the positioning of the primary and catalytic reactants need not result in isolated areas of oxide of the primary reactant 10′. For example, in situations in which the density of the catalytic reactant is sufficient, then effectively all of the primary reactant 10, can form oxide, resulting in a continuous, or near continuous, layer of oxide of the primary reactant 10′. “Localized heat” or “hot spots” implies that the heat is generated near the catalytic reactant. It does not necessarily mean that the entire surface of the wafer is not heated.

As discussed above, the localized heat generated from the first reaction will be sufficient to facilitate the second reaction, involving the primary reactant, to occur. In some embodiments, the temperature of the bulk substrate can be maintained beneath the temperature required for driving completion of the second reaction 70, but high enough to allow the first reaction 60 to occur, thereby generating localized heat 40. The localized heat created by the first reaction 60 drives the second reaction 70. As will be appreciated by one of skill in the art, the temperature of the chamber need not be maintained below any particular level in some embodiments.

In some embodiments, the bulk substrate temperature ensures that there is sufficient energy available for the first reaction. The bulk substrate temperature can also assist in supplying the activation energy for the second reaction. In these embodiments, the amount of localized heat 40 from the catalytic reactant 20 can be adjusted to take into account the amount of heat already present in the system due to the bulk atmosphere, and how much additional heat is required to drive the second reaction 70 forward to create the oxide of the primary reactant 50. Is some embodiments, the majority or even all of the heat is provided from the first reaction.

As will be appreciated by one of skill in the art, the primary and catalytic reactants can be selected based upon many different factors, such as the desired temperature of the reaction chamber or of the substrate, the desired amount of heat given off by the catalytic reactant's reaction, the amount of heat required for the second reaction, and the physical properties, such as the size of the ligands, which will determine the composition and arrangement of the monolayers. In some embodiments, the reactants are not metals. In one embodiment, the catalytic reactant is not a metal and does not result in the deposition of any material. In such embodiments, the catalytic reactant can be used to simply increase the localized temperature of the surface to drive the oxide formation reaction of the primary reactant. For example, the exothermic reaction can create heat simply by decomposing the exothermic reactant into volatile byproduct.

As will be appreciated by one of skill in the art, the shape (e.g., size of any ligands, bulkiness of the molecule, etc.), amount, and distribution (e.g., concentration or proximity) of the primary, exothermic, and oxygen containing reactants can alter the heating dynamics of the system dramatically. This allows for altering the resulting oxidization as well. One of ordinary skill in the art, in light of the present disclosure, will be able to determine the desired shape, amount, ratios, and distribution of the reactants. By surrounding areas of the primary reactant with the catalytic reactant, higher heat concentrations can be achieved. Additionally, by selective adherence of the catalytic reactant to the substrate, for example by a patterned reactive surface, selective conditioning, or selective blocking, one can determine which areas are going to be adequately to form oxide and thereby have a high enough heat to allow the oxide of the primary reactant to form. For additional information on these processes, see U.S. patent application Ser. No: 10/841585, filed May 7, 2004 and U.S. Pat. No. 6,391,785, issued May 21, 2002 herein incorporated by reference in their entireties. Using primary reactants that leave large areas of the surface available for binding after the primary reactant has established a monolayer can allow for more of the catalytic reactant to be chemisorbed. Using primary reactants that establish closely knit monolayers, so that there are very small or very few reactive sites available for the catalytic reactant can result in fewer molecules of catalytic reactant in the monolayer and thus lower temperature changes or more isolated temperature changes. In some embodiments, a relative scarcity of catalytic reactant is useful. For example, the formation of nanodots for memory applications is also feasible using this method. Similarly, altering the size of the catalytic reactant can alter the frequency in which it occurs on the surface, and thus its heating characteristics.

Examples of the primary reactant include organic metal or silicon compounds where it is relatively difficult to remove the organic ligands or where the organic ligands undergo incomplete oxide formation reaction. For example, due to incomplete oxide formation carbonates (-M-CO₂— bonds) may form in the case of primary reactants that rare earth metals or hydroxides (-M-OH— bonds) may form in the case of alkali and alkaline earth metals. However, it may also be that hydroxides will be formed in the case of rare earth metals while carbonates will be formed in case of alkali and alkaline earth metals. Further, mixtures of carbonates and hydroxides could also be formed. In addition, the “oxygen containing reactant” can have an effect on what species may form. As an example ozone can form carbonates and water hydroxides.

Examples of the primary reactant further include gamma-aminopropyl triethyl silane, hexamethyl disilazane, and silicon alkyl amide. In some embodiments, the primary reactant is selected from the group consisting of rare earth β-diketonates or derivates thereof, such as thd- and acac-compounds of Sc, Y, La, Ce, Pr, Nd, Sm, Eu, Gd, Tb, Dy, Ho, Er, Tm, Yb and Lu, and cyclopentadienyl compounds (-Cp, —C₅H₅) and derivates of those, such as cyclopentadienyl-, methylcyclopentadienyl-, ethylcyclopentadienyl-, and isopropylcyclopentadienyl compounds of Sc, Y, La, Ce, Pr, Nd, Sm, Eu, Gd, Th, Dy, Ho, Er, Tm, Yb and Lu.. In some embodiments the primary reactant is selected from the group consisting of La(thd)₃ and Y(thd)₃. Other possible primary reactants include alkali and alkaline earth metal β-diketonates and derivatives of those, such as thd- and acac-compounds of Be, Na, Mg, K, Ca, Rb, Cs and Ba, and alkali and alkaline earth metal cyclopentadienyl compounds and derivates of those, such as cyclopentadienyl-, (penta)methylcyclopentadienyl-, ethylcyclopentadienyl-, isopropylcyclopentadienyl compounds of Be, Na, Mg, K, Ca, Rb, Cs and Ba. In some embodiments, THF (tetrahydrofuran) adducts of the above mentioned alkali and alkaline earth metal cyclopentadienyl compounds are particularly preferred. Thus, ligands that can be removed from the primary reactant include beta-diketonates, such as thd (thd=2,2,6,6-tetramethyl-3,5-heptanedione) and alkyldisilazanes, such as hmds (hmds=N(Si(CH₃)₃)₂).

In some embodiments, aluminum β-diketonates are utilized, which have organic ligands coordinated to aluminum via oxygen atoms. Examples of such compounds include aluminum acetylacetonate Al(CH₃COCHCOCH₃)₃, often shortened as Al(acac)₃, and tris-(2,2,6,6-tetramethyl-3,5-heptanedionato)aluminum, often shortened as Al(thd)₃, Al(TMHD)₃ or Al(DPM)₃. Volatile halogenated aluminum beta-diketonates are also commercially available, such as aluminum hexafluoroacetylacetonate Al(CF₃COCHCOCF₃)₃, often shortened as Al(hfac)₃. These compounds are commercially available, for example from Strem Chemicals, Inc., Newburyport, Mass., USA. In some embodiments, the desired metal monolayer to be created comprises a rare earth element, such as lanthanide.

Catalytic reactants are preferably characterized by having lower activation barriers and being exothermic. Particular examples include metal compounds, for example alky compounds including alkylaluminum compounds such as trimethylaluminum TMA and derivates thereof, such as chlorodimethylaluminum. Other examples of catalytic reactants include acetylacetonates, such as Al(acac)₃, and metal alkoxides, such as titanium alkoxide, like titanium methoxide. However, the catalytic reactant need not comprise a metal. For example, in some embodiments the catalytic reactant may be selected from the group consisting of acetylacetones and alcohols, including hacac and EtOH. Compounds with more reactive ligands can provide more effective hot spots as they can be more exothermic.

The oxygen containing reactant is not limited in any way and may be, for example, ozone or water. In some preferred embodiments, the oxygen-containing reactant is ozone. As will be appreciated by one of skill in the art, the third reactant or “oxygen containing reactant” can be replaced with other reactants depending upon the nature and properties of the catalytic reactant. For example, the catalytic reactant could be photosensitive; thus, instead of an oxygen containing reactant, light could be added to drive the first reaction and to create heat to drive the second reaction. Additionally, as will be appreciated by one of skill in the art, the oxygen containing reactant can be added to the reaction chamber at various times. For example, the oxygen containing reactant can be added before the catalytic reactant is added or even before or with the primary reactant. The only requirement is that for the reaction to occur all three reactants should be at the substrate surface.

The end product need not be limited to an oxide of the primary reactant 10′. For example, in some embodiments, discussed below, the end product is a combination of oxide of the primary reactant and oxide of the catalytic reactant. In other embodiments, the reaction that occurs to the primary reactant 10 or the catalytic reactant 20 does not have to be an oxide formation reaction. Additionally, multiple monolayers can be created on top of each other.

In some embodiments, one may want to minimize the contribution of the catalytic reactant to the resulting film; for example, minimizing the amount of metal or metal oxide from the catalytic reactant. This can be achieved by selecting the appropriate reactant. To decrease the amount of Al in the film, for example, one can use Al(acac)₃ which is a larger molecule and incorporates less Al, but can provide effective hot spots due to its reactive beta diketonate ligand. Another possibility is to react the surface with a reactive ligand alone, such as acetylacetonate or alkoxide to get hot spots without introduction of another metal oxide.

In other embodiments, it can be desirous for the catalytic reactant to remain in the final film. An Al compound can provide hot spots and can also provide additional desirable properties in the resulting film. For instance, in shallow trench isolation (STI), Al₂O₃ can improve the thermal properties of SiO₂ (see for example, U.S. application Ser. No. 09/887199, filed Jun. 21, 2001, incorporated by reference in its entirety). An example employing this is provided in Example 2.

### EXAMPLES

The following examples, including the experiments conducted and results achieved are provided for illustrative purposes only and are not to be construed as limiting upon the teachings herein.

### Example 1

(a) La₂O₃ was deposited at 300° C. and below by ALD from La(thd)₃ and O₃ contains 10% carbon in the form of carbonate. A higher temperature of 350° C. is normally required to decompose the carbonate and remove nearly all the thd ligands to achieve pure La₂O₃ films. However, at reaction temperatures higher than 300° C., La(thd)₃ starts decomposing, which results in non-uniform La₂O₃ thin films. Thus, while a higher temperature is desired in order to obtain a higher purity film, during the initial formation of the La(thd)₃ monolayer, a lower temperature is desired to preserve uniformity of the initial monolayer. A catalytic reactant was used in this example to overcome this problem.

(b) At a temperature of 300° C. a La(thd)₃ (primary reactant) pulse was introduced into a reaction chamber to contact a wafer on which La₂O₃ was to be deposited. Following this, excess primary reactant was removed from the chamber. Next, an Al(CH₃)₃ (catalytic reactant) pulse was introduced into the chamber. Next, excess catalytic reactant was removed from the chamber. Following this, an O₃ (oxygen containing reactant) pulse was introduced into the chamber. The result was a decrease in the amount of carbon in the resulting La₂O₃ film at the reaction temperature of 300° C. to less than 0.6% instead of the typical 10% (the typical amount remaining without the catalytic reactant pulse) at a higher temperature of 350° C. The Al(CH₃)₃ compound allowed the lower temperature of 300° C. to be sufficient to significantly improve removal of the thd ligands. In this way a La₂O₃/Al₂O₃ mixture was deposited instead of pure La₂O₃, and there was no need to externally raise the temperature of the entire hot wall chamber and substrate to 350° C.

### EXAMPLE 2

First, a silicon compound such as gamma-aminopropyl triethoxy silane, hexamethyl disilazane or Si alkyl amide is pulsed into a reaction chamber to react with the surface of a wafer in a self-saturating manner. Next, unreacted silicon compound is removed from the chamber. After that, an Al compound such as Al(CH₃)₃ or Al(acac)₃ is pulsed into the reaction chamber. Following this, excess Al compound is removed from the chamber. Following this, ozone is then pulsed into the reaction chamber. A thin film comprising a mixture of Al₂O₃ and SiO₂ is obtained and the amount of Al₂O₃ incorporated into the film is controlled by the size of the Al compound (e.g., bigger ligands (e.g., Al(acac)₃) results in less Al in the compound and smaller ligands (e.g., Al(CH₃)₃) results in more Al in compound). As discussed above, the size and number of the ligands can determine the amount of the catalytic reactant on the surface.

### EXAMPLE 3

La(thd)₃ is chemisorbed on a surface of a wafer at less than about 300° C. Excess La(thd)₃ is removed from the reaction chamber. Following this Hacac or EtOH is pulsed into the reaction chamber and allowed to chemisorb to the surface. Next, excess Hacac or EtOH is removed from the chamber and O₃ is pulsed into the chamber, resulting in deposition of an La₂O₃/Al₂O₃ layer on the substrate. Finally, almost all O₃ is removed from the chamber along with reaction byproducts, if any. The Hacac or EtOH allows a higher purity La₂O₃/A₂O₃ monolayer to be produced than can be achieved by traditional ALD at this temperature, as these catalytic reactants only catalyze the full formation of an oxide of La(thd)₃ and do not substantially contribute to the film.

### EXAMPLE 4

La(thd)₃ is contacted with a surface of a wafer at less than about 300° C. Almost all remaining La(thd)₃ is removed from the reaction chamber. Following this, O₃ is pulsed into the chamber. Excess O₃ can be removed from the chamber. Next, Hacac or EtOH is pulsed into the reaction chamber and allowed to chemisorb to the surface. Almost all excess Hacac or EtOH is removed from the chamber. Following this, O₃ is pulsed into the chamber. Almost all excess O₃ can subsequently be removed from the chamber, along with reaction byproducts, if any. The Hacac or EtOH allows a higher purity La₂O₃ monolayer to be produced.

### EXAMPLE 5

A Ba- or Sr-precursor, for example the THF adduct bis(pentamethylcyclopentadienyl)barium Ba(C₅(CH₃)₅)THFₓ, where x is 0-2, is chemisorbed onto a substrate surface at 250° C. in a reaction chamber. Subsequently, almost all Ba- or Sr-precursor is removed from the chamber. Then a titanium alkoxide reactant, for example titanium methoxide, is pulsed into the reaction chamber and is chemisorbed to the available reactive sites. Almost all excess titanium precursors is then removed from the chamber.

In the following step ozone is introduced to the reaction chamber. Ozone reacts with the titanium precursor and forms titanium oxide. Further, the heat of that reaction facilitates the oxide formation reaction of barium or strontium that produces a BaTiO₃ or SrTiO₃ film with less impurity content than with a typical ALD method where the oxygen containing reactant is introduced after every metal precursor pulse and a catalytic reactant is not utilized. It is also possible to deposit BaₓSr₁₋ₓTiO₃ films if the precursor is changed from Ba to Sr, or from Sr to Ba in different cycles. The ratio of Sr to Ba pulses can be adjusted to deposit a film with the desired composition.

Although the foregoing invention has been described in terms of certain preferred embodiments, other embodiments will be apparent to those of ordinary skill in the art. The skilled artisan will readily appreciate that various compositions can be used for the catalytic, primary, and third reactant (for example, oxygen containing reactant). The skilled artisan will appreciate that variations of the methods and processes disclosed herein will have utility. Additionally, other combinations, omissions, substitutions and modifications will be apparent to the skilled artisan, in view of the disclosure herein. Accordingly, the present invention is not intended to be limited by the recitation of the preferred embodiments, but is instead to be defined by reference to the appended claims.

We claim:

1. A method for depositing a thin film on a substrate by an atomic layer deposition (ALD) type process comprising a plurality of cycles, at least one cycle comprising:
contacting a primary reactant to a surface of the substrate to form no more than a monolayer;
contacting a catalytic reactant to the surface; and
contacting the primary and catalytic reactants with one or more additional reactants,
wherein reaction of the catalytic reactant with at least one of the additional reactants generates a localized amount of heat that facilitates reaction of the primary reactant in a vicinity of the catalytic reactant to form the desired thin film.

2. The method of claim 1, wherein the primary and catalytic reactants are contacted with at least two additional reactants.

3. The method of claim 2, wherein at least one of the two additional reactants is an oxygen containing reactant.

4. The method of claim 1, wherein the primary and catalytic reactants are contacted with one additional reactant.

5. The method of claim 4, wherein the one additional reactant is an oxygen containing reactant.

6. The method of claim 1, wherein the primary and catalytic reactants both react with the same additional reactant.

7. The method of claim 1, wherein reaction of the primary reactant forms an oxide.

8. The method of claim 1, wherein reaction of the catalytic reactant forms an oxide.

9. The method of claim 1, wherein the thin film comprises an oxide of the catalytic reactant and an oxide of the primary reactant.

10. The method of claim 1, further comprising a removing excess unreacted primary reactant following contacting the primary reactant to the surface.

11. The method of claim 2, further removing excess unreacted catalytic reactant following contacting the catalytic reactant to the surface.

12. The method of claim 1, wherein the primary reactant is a metal reactant.

13. The method of claim 12, wherein reaction of the primary reactant produces a metal.

14. The method of claim 12, wherein the primary reactant is a beta-diketonate or cyclopentadienyl compound.

15. The method of claim 14, wherein the primary reactant is a rare earth beta-diketonate or cyclopentadienyl compound.

16. The method of claim 15, wherein the primary reactant is selected from the group consisting of thd-, acac-, cyclopentadienyl, methylcyclopentadienyl, ethylcyclopentadienyl and isopropylcyclopentadieny compounds of Sc, Y, La, Ce, Pr, Nd, Sm, Eu, Gd, Tb, Dy, Ho, Er, Tm, Yb and Lu.

17. The method of claim 12, wherein the primary reactant is an alkali or alkaline earth metal beta diketonate or cyclopentadienyl compound.

18. The method of claim 17, wherein the primary reactant is selected from the group consisting of thd-, acac-, cyclopentadienyl, methylcyclopentadienyl, ethylcyclopentadienyl and isopropylcyclopentadieny compounds of Be, Na, Mg, K, Ca, Rb, Cs and Ba.

19. The method of claim 17, wherein the primary reactant is a tetrahydrofuran adduct of an alkali alkaline earth metal cyclopentadienyl compound.

20. The method of claim 1, wherein the primary reactant is a silicon compound.

21. The method of claim 20, wherein the silicon compound is selected from the group consisting of gamma-aminopropyl triethyl silane, hexamethyl silane and silicon alkyl amide.

22. The method of claim 1, wherein the catalytic reactant is a metal reactant.

23. The method of claim 22, wherein reaction of the cataly

24. The method of claim 22, wherein the metal reactant is selected from the group consisting of alkyl compounds, acetylacetonates and metal alkoxides.

25. The method of claim 22, wherein the catalytic reactant is an alkylaluminum compound.

26. The method of claim 25, wherein the alkylaluminum reactant is trimethylaluminum or chlorodimethylaluninum.

27. The method of claim 22, wherein the catalytic reactant is Al(acac)₃.

28. The method of claim 22, wherein the catalytic reactant is selected from the group consisting of titanium alkoxides.

29. The method of claim 1, wherein the catalytic reactant does not comprise a metal.

30. The method of claim 29, wherein the catalytic reactant is selected from the group consisting of acetylacetonates and alcohols.

31. A method for thin film deposition by atomic layer deposition (ALD) in a reaction chamber, said method comprising:
performing a low activation energy reaction that requires a first amount of activation energy and that results in the creation of a first amount of heat; and
performing a high activation energy reaction that requires a second amount of activation energy, wherein said second amount of activation energy is greater than said first amount of activation energy, wherein said high activation energy reaction is aided by the first amount of heat from the low activation energy reaction, and wherein both of said reactions occur on a surface of a wafer housed in a reaction chamber.

32. A method for depositing a thin film on a substrate by atomic layer deposition (ALD) in a reaction chamber, said method comprising:
pulsing a vapor phase primary reactant into the reaction chamber, wherein said primary reactant chemisorbs to a surface of the substrate in said reaction chamber, and wherein said reaction chamber is at a temperature below a temperature sufficient to decompose the reactant;
removing primary reactant that has not chemisorbed to the substrate from the reaction chamber;
pulsing a vapor phase catalytic reactant into the reaction chamber, wherein the catalytic reactant chemisorbs to the substrate in said reaction chamber;
removing catalytic reactant that has not chemisorbed to the substrate from the reaction chamber; and
providing an oxygen containing reactant to the reaction chamber, wherein reaction of the catalytic reactant with the oxygen containing reactant yields an amount of heat to the surface of the wafer sufficient to increase formation of an oxide of the primary reactant, and wherein the reaction of the catalytic reactant with the oxygen containing reactant requires less energy than the formation of the oxide of the primary reactant.

33. The method of claim 32, wherein the catalytic and primary reactants are pulsed into the reaction chamber at the same time.

34. The method of claim 32, wherein the catalytic reactant is pulsed into the reaction chamber before the primary reactant is pulsed into the chamber.

35. The method of claim 32, wherein the thin film comprises a two-dimensional array of nanodots.

36. The method of claim 35, wherein the nanodots are randomly shaped and randomly distributed throughout the two dimensional array.

37. The method of claim 32, wherein the bulk temperature of the substrate is not significantly changed via a reaction chamber heat source throughout the method.

38. The method of claim 32, wherein the thin film comprises an oxide of the primary reactant and an oxide of the catalytic reactant.

39. The method of claim 32, wherein the catalytic reactant does not contribute to the thin film.

40. The method of claim 32, wherein the catalytic reactant does not comprise a metal.

41. The method of claim 32, wherein the temperature of the reaction chamber is no more than approximately 300° C.

42. A method for creating nanodots on a substrate in a reaction chamber by an atomic layer deposition (ALD) type process comprising a plurality of cycles, each cycle comprising:
adsorbing a primary reactant to a surface of the substrate to form no more than a monolayer;
adsorbing a catalytic reactant to the substrate surface such that it chemisorbs to one or more binding sites on the substrate surface; and
reacting the primary and catalytic reactants with an oxygen containing reactant,
wherein reaction of the catalytic reactant with the oxygen containing reactant generates a zone of increased heat that facilitates formation of an oxide of the primary reactant within the zone of increased heat.

43. A method for depositing a thin film on a substrate by an atomic layer deposition (ALD) type process comprising a plurality of cycles, at least one cycle comprising:
adsorbing a lanthanum reactant to a surface of the substrate to form no more than a monolayer;
adsorbing an aluminum reactant to the surface; and
reacting the adsorbed lanthanum and aluminum reactants with an oxygen containing reactant, wherein formation of an oxide of the aluminum reactant generates a localized amount of heat that facilitates formation of an oxide of the lanthanum reactant in a vicinity of the aluminum reactant.

44. The method of claim 43, wherein the lanthanum reactant is La(thd)₃ and the aluminum reactant is trimethylaluminum.

45. The method of claim 43, wherein the oxygen-containing reactant is ozone.
